(19) United States
(12) Patent Application Publication
(10) Pub. No.: US 2010/0154710 A1
(43) Pub. Date: Jun. 24, 2010

(54) IN-VACUUM DEPOSITION OF ORGANIC MATERIALS

(76) Inventors: Scott Wayne Priddy, Saint Louis Park, MN (US); Chad Michael Conroy, Stillwater, MN (US)

Correspondence Address: KAGAN BINDER, PLLC, SUITE 200, MAPLE ISLAND BUILDING, 221 MAIN STREET NORTH, STILLWATER, MN, 55082, US

(21) Appl. No.: 12/639,508

(22) Filed: Dec. 16, 2009

Related U.S. Application Data
(60) Provisional application No. 61/138,682, filed on Dec. 18, 2008.

(51) Int. Cl. C23C 14/00

(52) U.S. Cl. 118/724; 118/50

(57) ABSTRACT

Vapor depositions sources, systems, and related deposition methods. Vapor deposition sources for use with materials that evaporate or sublime in a difficult to control or otherwise unstable manner are provided. The present invention is particularly applicable to deposition of organic material such as those for forming one or more layer in organic light emitting devices.

### CROSS REFERENCE TO RELATED APPLICATIONS

This application claims the benefit of U.S. Provisional Application Ser. No. 61/138,682 filed Dec. 18, 2008 entitled IN-VACUUM DEPOSITION SOURCES, SYSTEMS, AND RELATED METHODS FOR DEPOSITION OF ORGANIC MATERIALS, which is hereby incorporated by reference in its entirety for all purposes.

### TECHNICAL FIELD

The present invention relates to vapor depositions sources, systems, and related deposition methods. More particularly, the present invention relates to vapor deposition sources for use with materials that evaporate or sublime in a difficult to control or otherwise unstable manner. For example, the present invention is particularly applicable for depositing organic materials such as those for use in an organic light-emitting device (OLED).

### BACKGROUND

An organic light-emitting device, also referred to as an organic electroluminescent device, is typically constructed by sandwiching two or more organic layers between first and second electrodes. In a passive matrix organic light-emitting device of conventional construction, a plurality of laterally spaced light-transmissive anodes, for example indium-tin-oxide anodes, are formed as first electrodes on a light-transmissive substrate such as, for example, a glass substrate. Two or more organic layers are then formed successively by vapor deposition of respective organic materials from respective sources, within a chamber held at reduced pressure, typically less than a millitorr. A plurality of laterally spaced cathodes is deposited as second electrodes over an uppermost one of the organic layers. The cathodes are oriented at an angle, typically at a right angle, with respect to the anodes.

Applying an electrical potential (also referred to as a drive voltage) operates such conventional passive matrix organic light-emitting devices between appropriate columns (anodes) and, sequentially, each row (cathode). When a cathode is biased negatively with respect to an anode, light is emitted from a pixel defined by an overlap area of the cathode and the anode, and emitted light reaches an observer through the anode and the substrate.

In an active matrix organic light-emitting device, an array of anodes are provided as first electrodes by thin-film transistors, which are connected to a respective light-transmissive portion. Two or more organic layers are formed successively by vapor deposition in a manner substantially equivalent to the construction of the passive matrix device described above. A common cathode is deposited as a second electrode over an uppermost one of the organic layers. The construction and function of an exemplary active matrix organic light-emitting device is described in U.S. Pat. No. 5,550,066, the entire disclosure of which is incorporated by reference herein for all purposes.

Organic materials, thicknesses of vapor-deposited organic layers, and layer configurations, useful in constructing an organic light-emitting device, are described, for example, in U.S. Pat. Nos. 4,356,429, 4,539,507, 4,720,432, and 4,769,292, the entire disclosures of which are incorporated by reference herein for all purposes.

An exemplary organic material used in OLED's is referred to as Alq3 (Aluminum Tris (8-Hydroxyquinoline)). This material and others like it are typically characterized as having poor thermal conductivity, which makes it difficult to uniformly heat the material to vaporize it. Moreover, these organic materials are typically provided in powder or granular form, which also makes it difficult to uniformly heat the material. Such materials may also be in a liquid state either at room temperature or deposition temperature or both. Such non-uniformity in heating the material causes non-uniform vaporization of the material (by sublimation). Such non-uniform vapor flux, directed at a substrate or structure, will cause the formation of an organic layer thereon which will have a non-uniform layer thickness in correspondence with the non-uniform vapor flux.

A source for thermal physical vapor deposition of organic layers onto a structure for making an organic light-emitting device is described in U.S. Pat. No. 6,237,529 to Spahn. Another source for deposing organic layers is described in U.S. Pat. No. 6,837,939 to Klug et al. The Spahn and Klug et al. sources for depositing organic layers are representative of the current state of the art. These sources attempt to address the non-uniformity experienced in depositing these materials by using solid or bulk material instead of the granular form of the material. The Spahn source uses an arrangement of baffles and apertured plates to help minimize particulates that can be ejected by the source material but does not address the above-noted uniformity issue. The Klug et al. source uses a mechanism that advances compacted pellets of deposition material into a heated zone and an arrangement of baffles and apertured plates to address the uniformity problem. However, the Klug et al. source is complex and cannot regulate and/or meter the vaporized material.

### SUMMARY

The present invention thus provides vapor deposition sources and deposition methods that provide stable and controllable flux of materials that evaporate or sublime non-uniformly or in an unstable manner. Such materials are typically characterized as having one or more of low or poor thermal conductivity, a granular, flake, or powder consistency, and one or more inorganic components. Moreover, such materials typically sublime from a solid state rather that evaporate from a liquid (molten) state and do so in an unstable or difficult to regulate manner. Materials that sublime are also sensitive to thermal treatment as they may sublime as desired yet decompose undesirably within a narrow range of temperatures. Such materials are not required to be solid and may be in a liquid state either at room temperature or deposition temperature or both.

Deposition sources and methods in accordance with the present invention thus provide the ability to controllably heat a deposition material in a manner that optimizes evaporation or sublimation and minimizes non-uniform heating, heating of undesired portions of a deposition material within a crucible, and undesired decomposition of a deposition material when heated to evaporate or sublime the material.

Deposition sources and methods of the present invention are particularly applicable to depositing organic materials for forming one or more layers in organic light emitting devices.

In an aspect of the present invention, a vacuum deposition source is provided. The vacuum deposition source comprises an enclosure configured to be positioned within a vacuum chamber of a vacuum deposition system. The enclosure comprises one or more portions separable from each other; a valve positioned at least partially within the enclosure, the valve having an input side and an output side; a crucible comprising a closure plate wherein the closure plate is in communication with the input side of the valve; a nozzle comprising at least one exit orifice, the nozzle at least partially positioned in the enclosure and in communication with the output side of the valve; a heating device at least partially surrounding the valve; and a valve actuator operatively connected to the valve and configured to operate in vacuum.

In another aspect of the present invention, a vacuum deposition system is provided. The vacuum deposition system comprises a vacuum chamber; an enclosure configured to be positioned within a vacuum chamber of a vacuum deposition system, the enclosure comprising one or more portions separable from each other; a valve positioned at least partially within the enclosure, the valve having an input side and an output side; a crucible comprising a closure plate wherein the closure plate is in communication with the input side of the valve; a nozzle comprising at least one exit orifice, the nozzle at least partially positioned in the enclosure and in communication with the output side of the valve; a heating device at least partially surrounding the valve; and a valve actuator operatively connected to the valve and configured to operate in vacuum a deposition material provided in the crucible; and a substrate positioned in the vacuum chamber and relative to the nozzle of the vacuum deposition source.

In yet another aspect of the present invention, a vacuum deposition source is provided. The vacuum deposition source comprises an enclosure configured to be positioned within a vacuum chamber of a vacuum deposition system, the enclosure comprising one or more portions separable from each other; a valve positioned at least partially within the enclosure, the valve having an input side and an output side; a crucible comprising a closure plate wherein the closure plate is in communication with the input side of the valve; a nozzle at least partially positioned in the enclosure and in communication with the output side of the valve, the nozzle comprising a plurality of output orifices and a flux monitoring jet distinct from the plurality of output orifices wherein the flux monitoring jet emits a flux proportional to the output flux of the plurality of output orifices; a heating device at least partially surrounding the valve; and a valve actuator operatively connected to the valve and configured to operate in vacuum.

### BRIEF DESCRIPTION OF THE DRAWINGS

The accompanying drawings, which are incorporated in and constitute a part of this disclosure, illustrate several aspects of the present invention and together with description of the exemplary embodiments serve to explain the principles of the invention. A brief description of the drawings is as follows:

FIG. 1 is a perspective view of an exemplary vapor deposition source in accordance with the present invention.

FIG. 2 is a schematic cross-sectional view of the vapor deposition source of FIG. 1.

FIG. 3 is a schematic perspective partial cross-sectional view of the deposition source of FIG. 1 taken along a different cross-sectional line than that of FIG. 2.

FIG. 4 is a schematic cross-sectional view of a vapor deposition source similar to the source shown in FIG. 1 and having a different exemplary nozzle.

FIG. 5 is another exemplary deposition source in accordance with the present invention showing, in particular, an alternate valve orientation.

FIG. 6 is a schematic view of a vapor deposition source similar to the source shown in FIG. 1 and having a different exemplary nozzle wherein the nozzle comprises a heating device.

FIGS. 7-13 show schematic views of an exemplary vapor deposition source configured for use in vacuum in accordance with the present invention.

FIGS. 14-21 show schematic views of another exemplary vapor deposition source configured for use in vacuum in accordance with the present invention.

FIGS. 22-28 show schematic views of a deposition nozzle in accordance with the present invention.

FIGS. 29-30 show schematic views of a bank of plural deposition sources and nozzles in accordance with the present invention.

### DETAILED DESCRIPTION

The exemplary embodiments of the present invention described herein are not intended to be exhaustive or to limit the present invention to the precise forms disclosed in the following detailed description. Rather the exemplary embodiments described herein are chosen and described so those skilled in the art can appreciate and understand the principles and practices of the present invention.

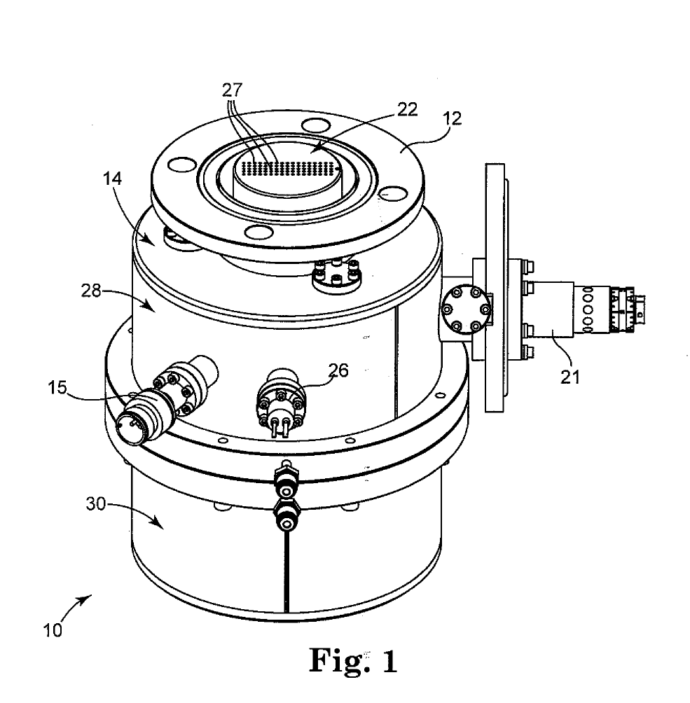

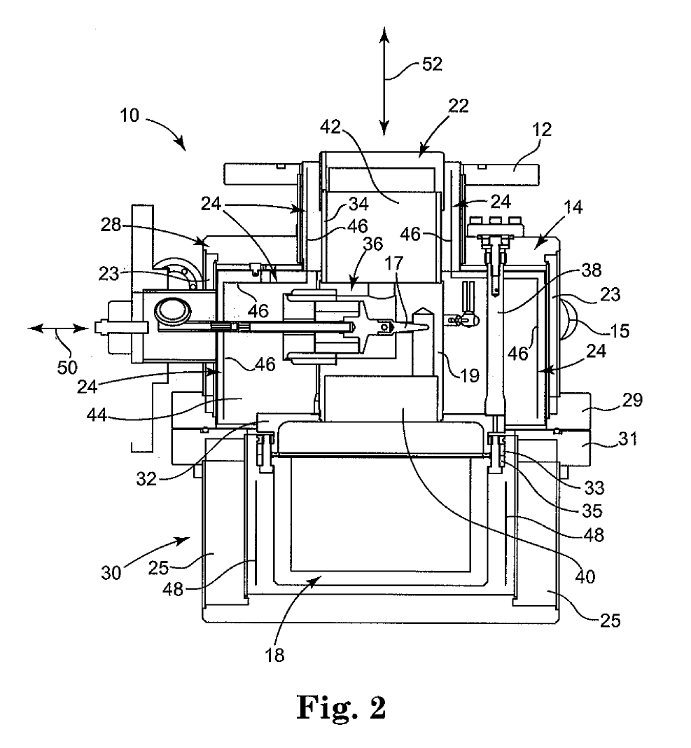

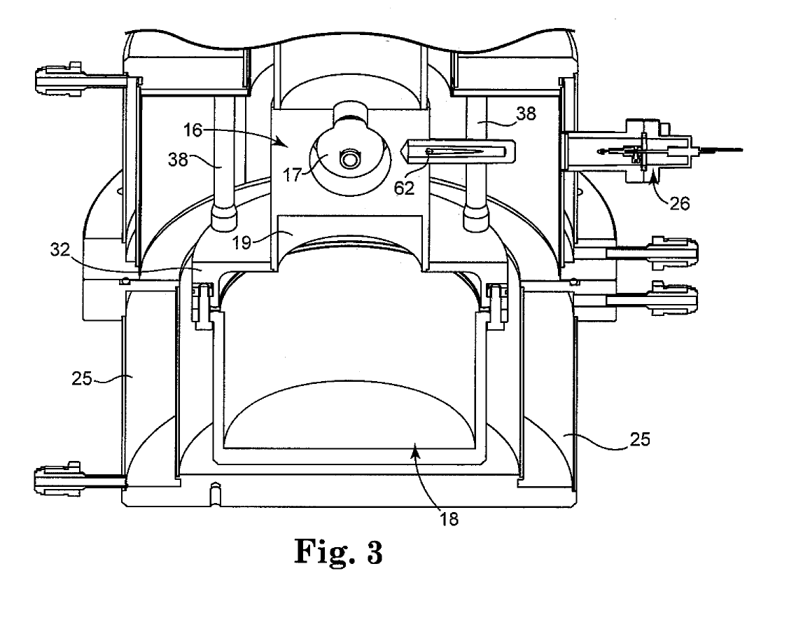

Referring initially to FIGS. 1-3 an exemplary vapor deposition source 10 in accordance with the present invention is illustrated. In FIG. 1 a perspective view of deposition source 10 is shown. In FIG. 2 a schematic cross-sectional view of deposition source 10 is shown. FIG. 3 shows a partial schematic cross-sectional perspective view along a different cross section line than that of FIG. 2.

The exemplary deposition source 10 illustrated in FIGS. 1-3 is designed for vacuum deposition and, as illustrated, generally includes mounting flange 12 for attaching deposition source 10 to a deposition system (not shown), body 14 attached to flange 12, valve 16, crucible 18 comprising internal space 20, nozzle 22, and heater assembly 24 for providing heat, preferably radiant, to evaporate or sublime material located in crucible 18 and prevent deposition of such material on undesired surfaces (valve 16 and nozzle 22, for example). Valve 16 comprises valve portion 17 and valve body 19. Deposition source 10, as shown, also preferably comprises water jackets 23 and 25 for cooling, power feedthrough 15 for providing power to heater assembly 24, and feedthrough 26 for a thermocouple, or similar sensor.

Body 14 of exemplary deposition source 10, as shown, comprises first body portion 28 attached to mounting flange 12 and second body portion 30 attached to first body portion 28. Body 14 preferably comprises stainless steel as is well known for vacuum deposition components. Body 14 is preferably designed so crucible 18 can be accessed and/or removed for maintenance, replacement, and so deposition material can be added/removed as needed. In particular, first body portion 28 includes flange 29 removably connected to flange 31 of second body portion 30. In the illustrated embodiment, second body portion 30 is separable from first body portion 28 to access crucible 18.

Crucible 18, as shown, is reparably attached to plate 32 by flange 33 of plate 32 and flange 35 of crucible 18. The connection between crucible 18 and plate 32 is preferably vacuum tight and resealable. For example, a Conflat® style seal can be used which seal comprises flanges having knife-edges that embed into a soft metal seal gasket such as a copper or niobium gasket or the like. Alternatively, a graphite seal material can be used such as a flexible graphite gasket material positioned between polished flange surfaces. Such graphite material is available from GrafTech Advanced Energy Technology, Inc. of Lakewood, Ohio.

Plate 32, as shown, is welded to valve body 19 to provide a vacuum tight enclosure between crucible 18 and valve 16. In the illustrated design, second body portion 30 can be separated from first body portion 28 to access crucible 18 and crucible 18 can be separated from plate 32 to replace crucible 18, add/remove source material, for example.

Plate 32, as shown, is attached to valve body 19, which is attached to nozzle 22, via tube 34 as shown. Plate 32, valve body 19, and tube 34 are preferably welded to each other but other connection techniques can be used for permanent connection of one or more of the components of assembly 36 (brazing, for example) or resealable connections (using gaskets, for example). Crucible 18, plate 32, valve body 19, and tube 34 preferably comprise vacuum compatible materials such as titanium and stainless steel and the like. Preferably, as illustrated, assembly 36 comprising crucible 18, plate 32, valve body 19, tube 34, and nozzle 22 is thermally isolated from body 14 of deposition source 10. In the illustrated design, such isolation is accomplished by supporting or hanging assembly 36 from first body portion 28. Preferably, support legs 38 connected to first body portion 28 and connected to plate 32, as shown, are used.

Preferably, as illustrated, crucible 18, plate 32, valve body 19, and valve portion 17 define first vacuum zone 40 distinct from second vacuum zone 42 defined by the valve body 19, valve portion 17, tube 34, and nozzle 22. Communication between first and second vacuum zones, 40 and 42, respectively, is controlled by valve 16. A third distinct vacuum zone 44 is defined by the space between first and second body portions 28 and 30, respectively, and crucible 18, plate 32, valve body 19, tube 34, and nozzle 22. Third vacuum zone 44 is in communication with a vacuum chamber (not shown) when the deposition source 10 is attached to such vacuum chamber. In use, third vacuum zone 44 is preferably maintained at a vacuum level that minimizes convective heat transfer between first and second body portions 28 and 30, respectively, and crucible 18, plate 32, valve body 19, tube 34, and nozzle 22. For example, maintaining third vacuum zone 44 below about 50 millitorr helps to minimize such convective heat transfer.

Deposition source 10 includes heater assembly 24 for providing thermal energy that functions to evaporate or sublime material located in crucible 18. Crucible 18 or a desired portion(s) thereof can be heated radiatively (indirectly) or can be heated directly such as by resistively or conductively heating crucible 18 or a desired portion(s) of crucible 18. Combinations of indirect, direct, radiative, resistive, conductive heating, and the like can be used. In the illustrated embodiment, heater portion 46 is schematically shown positioned in first body portion 28. Plural distinct heaters can be used. Preferably such a heater comprises one or more filaments that are resistively heated to provide radiant thermal energy. Here, heater portion 46 radiatively heats nozzle 22, tube 34, valve 16, and plate 32. Such heating may be direct, indirect, or combinations thereof. One or more heaters can be used that are spaced from and/or in contact with component(s) desired to be heated. Heating such components functions to prevent deposition of material onto such components especially valve body 19 and valve portion 17, which could cause unwanted build up of material. Crucible 18 is partly heated by conduction between valve 16, plate 32 and crucible 18 as well as radiation from plate 32 and valve body 19. In this design, the deposition material in interior space 20 of crucible 18 is primarily heated from above as the conductive heating between plate 32 and crucible 18 is minimal. That is, radiative heat from plate 32 and valve body 19 is the primary source of heating for crucible 18 and particularly for deposition material provided in crucible 18.

Second body portion 30 can include one or more optional heater(s) 48 for heating crucible 18, directly or indirectly. Such heater can be spaced from and/or in contact with crucible 18. Preferably, heater portion 48 for second body portion 30 is distinct from heater portion 46 in first body portion 28 so heater portion 46 and heater portion 48 can be operated independently from each other. Whether or not second body portion 30 includes one or more heaters to heat crucible 18 depends on factors such as the particular deposition material, desired flux uniformity, desired flux rate, crucible design, deposition source geometry, and combinations thereof, for example. Deposition source 10 can be designed to include plural heaters (of the same of different types) in any of first and second body portions 28 and 30, respectively, or within any of the vacuum zones. Thus, depending on the particular deposition material, any single or combination of heaters can be used. Determining what portion(s) of deposition source 10 is heated, not heated, or cooled, and how, is generally at least partially dependent on the characteristics of the particular deposition material used and can be determined empirically to obtain desired performance objective(s) such as one or more of deposition uniformity, flux rate, flux stability, material usage efficiency, and minimizing coating of valve components for example.

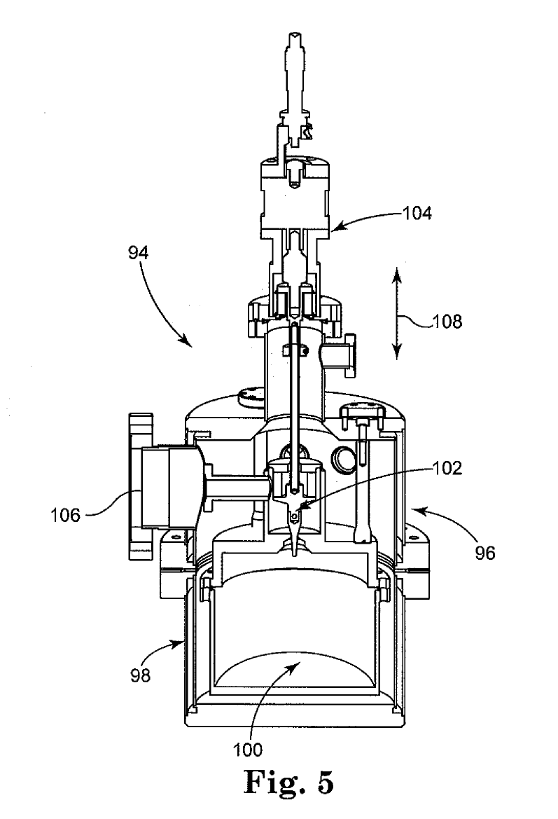

Valve 16 is designed for vacuum use and can preferably withstand being heated during use of deposition source 10. Valve 16 preferably includes a driver or actuator 21 (see FIG. 1) to provide computer (signal-based) control of valve 16. An exemplary actuator is Part No. SMC-II, available from Veeco Compound Semiconductor Inc. of St. Paul, Minn. Depending on the deposition material and/or deposition process valve 16 can provide regulating, metering, on/off functionality, combinations thereof, for example. Preferably, valve 16 is capable of creating a pressure differential between first and second vacuum zones, 40 and 42, respectively, such as for providing a backpressure in first vacuum zone 40. As shown, valve portion 17 moves along an axis (identified by reference numeral 50) different from the axis of material evaporation and/or sublimation from crucible 18 (identified by reference numeral 52). In an alternative design, valve portion 17 can move along the axis of material evaporation as shown schematically in FIG. 5 and described below. Effusion cells having valves for use in the context of vapor deposition are described in U.S. Pat. No. 6,030,458 to Colombo et al., for example, the entire disclosure of which is incorporated by reference herein for its entire technical disclosure including, but not limited to, the disclosure of such valves and for all purposes.

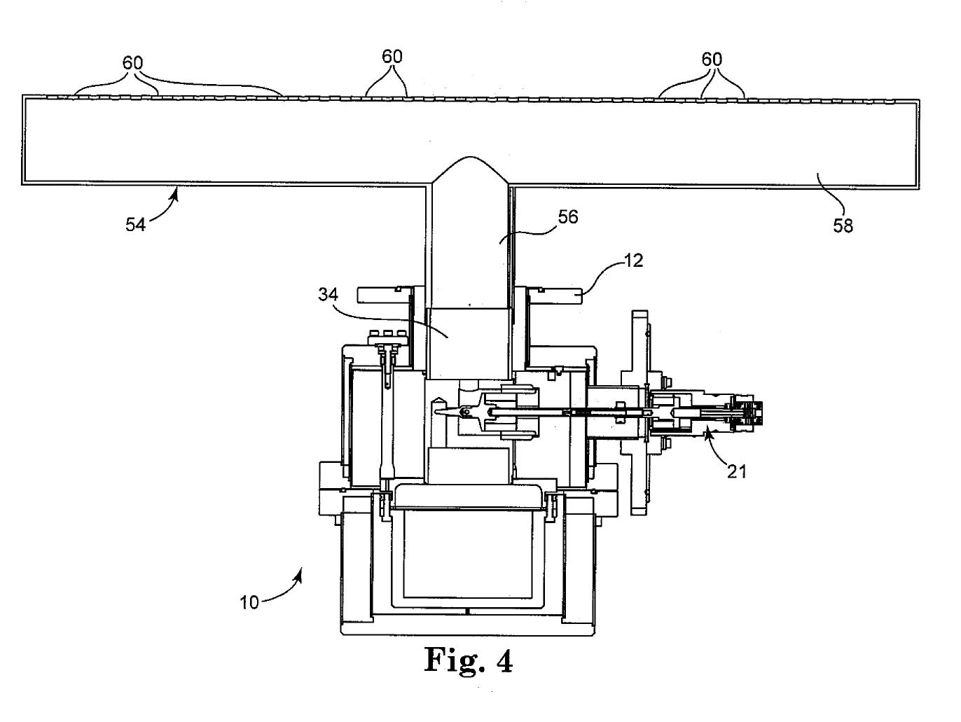

Deposition source 10, as shown, includes nozzle 22. Nozzle 22 is preferably designed to provide desired deposition performance. Typically, nozzle 22 includes one or more openings (orifices) for emitting and/or directing deposition material in a predetermined direction and/or rate. Nozzle orifices are preferably arranged to provide optimal uniformity across a wide substrate. Typically there is a uniform set of orifices across the nozzle with a higher concentration near the ends of the nozzle to compensate for the flux roll off at the end of the nozzle. As illustrated, nozzle 22 comprises plural exit orifices 27 but a single exit orifice may be used. Factors used in designing the nozzle include deposition material, deposition uniformity, deposition rate, deposition system geometry, and the number, type, and size of substrates deposited on. Such nozzles can be designed using empirical data, information, and/or techniques. Nozzles that can be used with deposition sources in accordance with the present invention are available from Veeco Compound Semiconductor Inc. of St. Paul, Minn. and described below. An alternative nozzle 54 is illustrated in FIG. 4 and is designed to provide increased areal coverage by the emitted vapor deposition flux. As shown, nozzle 54 comprises tube 56 and body portion 58 having plural exit apertures 60. Tube 56 functions to space body portion 58 from flange 12 of deposition source 10. Such spacing is dependent on the particular deposition application for which deposition source 10 is used. As shown, body portion 58 extends linearly and orthogonally relative to tube 56. Body portion 58 may be provided at any desired angle relative to tube 56. As shown, body portion 58 comprises a tube (cylinder) but may comprise a planar structure such as a cube, rectangle, or disk or may comprise an arcuate structure such as a sphere or similar arcuate surface or the like. Body portion 58 may comprise any number of exit apertures (including a single exit aperture). Such exit apertures may comprise any shape (e.g., circular, elliptical, square, rectangular) or combinations of such shapes. Nozzle 54 does not need to be symmetric and the density of such exit apertures may vary between regions of nozzle 54. A nozzle is not required for some applications and a single orifice may be sufficient. That is, tube 34 also functions as a nozzle in the absence of nozzle 22 and nozzle 54.

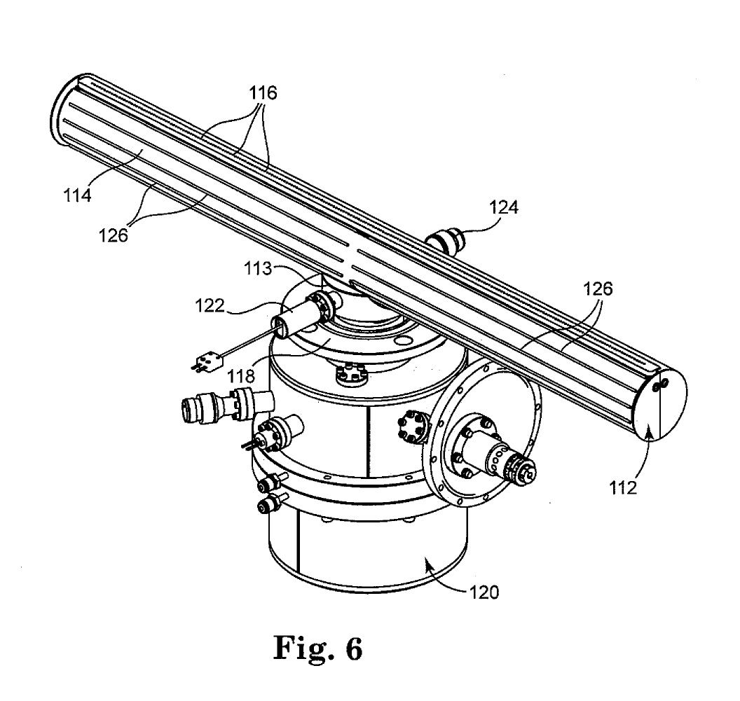

An alternative nozzle 112 is illustrated in FIG. 6. As shown, nozzle 112 comprises tube 113 and body portion 114 having plural exit apertures 116. Tube 113 functions to space body portion 114 from flange 118 of deposition source 120. Tube 113 also functions to house thermocouple feedthrough 122 and power feedthrough 124 for nozzle 112. Nozzle 112 also comprises heating elements 126 connected to power feedthrough 124 the temperature of which can be controlled by feedback from thermocouple feedthrough 122. Plural heating elements are shown but a single element may be used Heating elements 126 are shown on an exterior surface of nozzle 112 but may be provided inside nozzle 112. As shown, body portion 114 extends linearly and orthogonally relative to tube 113. Body portion 114 may be provided at any desired angle relative to tube 113. As shown, body portion 114 comprises a tube (cylinder) but may comprise a planar structure such as a cube, rectangle, or disk or may comprise an arcuate structure such as a sphere or similar arcuate surface or the like. Body portion 114 may comprise any number of exit apertures (including a single exit aperture). Such exit apertures may comprise any shape (e.g., circular, elliptical, square, rectangular) or combinations of such shapes. Nozzle 112 does not need to be symmetric and the density of such exit apertures may vary between regions of nozzle 112.

Deposition source 10 also preferably includes other components and/or design aspects as needed depending on the particular deposition material and/or deposition process. For example, the illustrated deposition source 10 includes a thermocouple 62 for temperature measurement and is used for controlling deposition flux. Thermocouple 62 is preferably designed to be in contact with valve body 19. Type-K and Type-J thermocouples are preferred but any temperature measurement device can be used. Plural thermocouples or temperature sensors or control systems can be used. The illustrated deposition source 10 also incorporates cooling jacket 25, preferably water (any fluid can be used including gas(es), for managing and/or cooling desired portions of deposition source 10.

Another exemplary deposition source 94 in accordance with the present invention is illustrated in FIG. 5. Deposition source 94 includes first body portion 96, second body portion 98, crucible 100, valve 102, valve actuator 104, and nozzle port 106. Deposition source 94 is similar to deposition source 10 shown in FIGS. 1 and 2 but has a different valve orientation. That is, valve 102 comprises drive axis 108, which is oriented along the direction of material evaporation and/or sublimation from crucible 100. Any of the crucibles described herein may be used in deposition source 94.

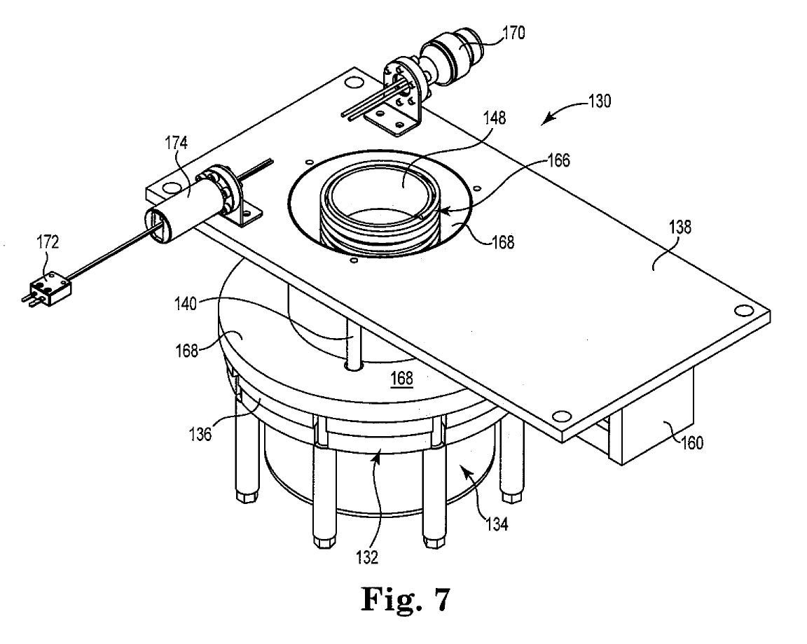

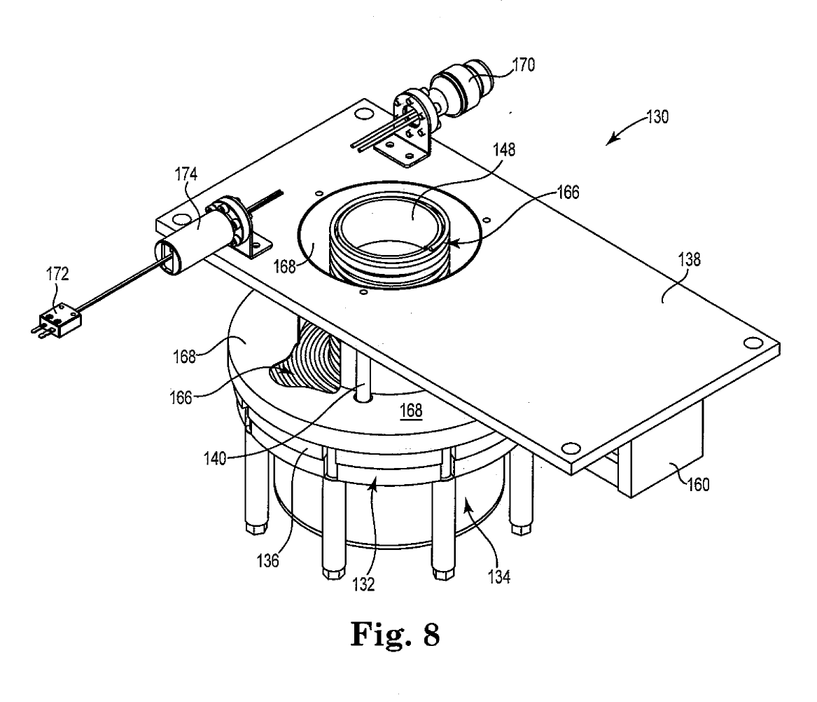

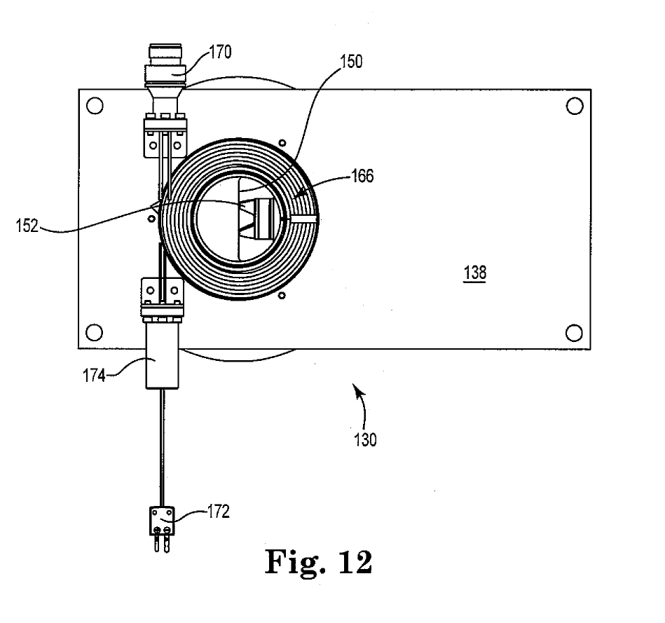

FIGS. 7-12 show another exemplary deposition source 130 in accordance with the present invention. Illustrated deposition source 130 is preferably designed and configured to be at least partially positioned within a vacuum deposition chamber (not shown). In a preferred embodiment, deposition source 130 is designed and configured to be substantially or entirely positioned within a vacuum deposition chamber (not shown). Advantageously, having the entire deposition source in vacuum, or at least a substantial portion of the deposition source, allows the deposition source to be moved relative to a substrate positioned within the vacuum chamber. For example, deposition source 130 can be positioned on a robot or the like that allows deposition source 130 to be moved relative to a substrate. An exemplary application where an in-vacuum deposition source is particularly useful is for forming a layer(s) of an organic material on a substrate(s) in the manufacture of organic light emitting devices.

Deposition source 130 of FIGS. 7-12 is similar to deposition source 10 described above and shown in FIGS. 1-6 except that deposition source 10 of FIGS. 1-6 is designed to be positioned outside of a deposition chamber as mounted on a flange of the deposition chamber. Designing a deposition source that can be positioned entirely in vacuum is challenging and many obstacles need to be addressed. Moreover, designing such a deposition source for depositing organic materials used in organic light emitting devices is particularly challenging. Careful control of many thermal aspects of the deposition source is required. For example, it is desirable to heat organic deposition material from the top to heat the exposed surface of the deposition material and minimize heating of other portions of the deposition material. This is generally attributed to a property of such organic materials that causes certain materials to easily degrade at a temperature near a desired deposition temperature. Indeed, certain organic materials degrade in a temperature range that overlaps with the temperature range desired for deposition. Additionally, it is also desirable to minimize heat radiated to the substrate from the deposition source.

Referring to FIGS. 7-13 generally, deposition source 130 comprises enclosure 132 including crucible 134 and closure plate 136 that are preferably separable from each other. Closure plate 136 is preferably attached to mounting plate 138 by plural support legs 140. Mounting plate 138 can be used to mount deposition source 130 within a vacuum deposition chamber (not shown). Crucible 134 is preferably designed to hold a desired amount of deposition material and may include any number of chambers or cells including a single interior chamber as illustrated. Exemplary crucibles that can be used are also described in Applicant's copending U.S. patent application titled “Vapor Deposition Sources and Methods,” having Ser. No. 12/002,526, and attorney docket No. VII0004/US, the entire disclosure of which is incorporated herein for all purposes.

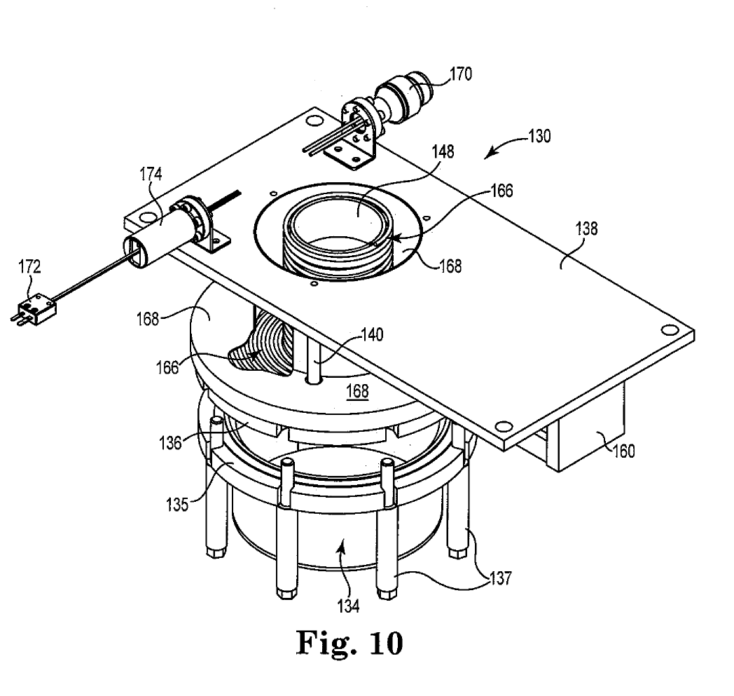

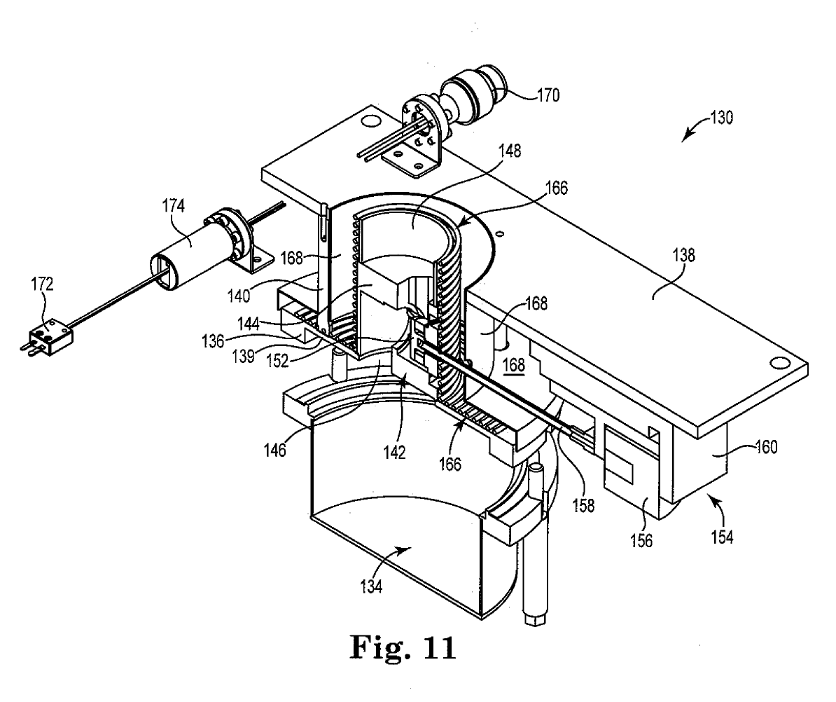

Crucible 134 is preferably designed to be detachable from closure plate 136 such as is illustrated in FIGS. 10 and 11. An appropriate seal is preferably provided between crucible 134 and closure plate 136. An exemplary preferred seal comprises a graphite gasket that is clamped between a flat surface of crucible 134, such as flange 135, and a flat surface of closure plate 136. As shown, bolts 137 are used to provide a compressive force between flange 135 and closure plate 136. Seals that include metal gaskets and flanges having a knife-edge may also be used.

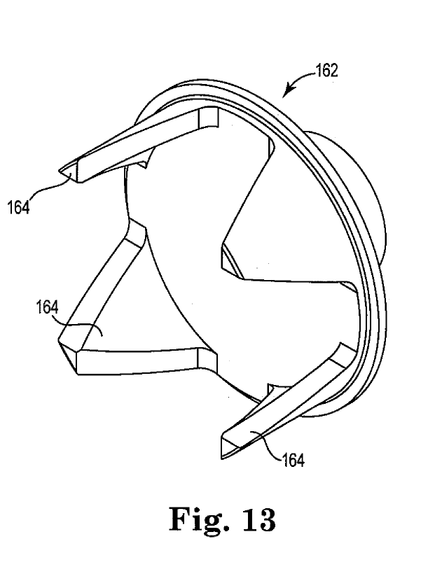

Closure plate 136, as shown, includes valve assembly 142. Valve assembly 142 includes valve body 144 with input and output regions 146 and 148, valve seat 150, valve 152, and valve actuator 154. Valve actuator 154 includes motor 156, drive shaft 158, and mounting plate 160. An exemplary valve 162 that can be used is shown in FIG. 13. As shown, valve 162 comprises plural spaced apart tapered arms 164. The space between arms 164 is configured to provide a gradual increase in flux as valve 162 is opened thereby reducing an initial burst or release of pressure.

As shown, input side 146 of valve assembly 142 is attached to closure plate 136 and output side 148 of valve 152 is configured to be attached to a nozzle (not shown). Exemplary nozzles that can be used are described below. In this configuration, vapor from deposition material provided within crucible 134 enters valve body 144 at input side 146 of valve body 144 and exits valve body 144 at output side 148 of valve body 144 as controlled by valve 152.

Deposition source 130 is preferably designed to heat deposition material provided within crucible 134 in a controlled manner. In particular, when the deposition material comprises organic material such as is used in the manufacture of organic light emitting devices, the deposition material is preferably heated from above. That is, it is preferred to provide radiant heat to the top (exposed) surface of the deposition material provided in crucible 134. Moreover, it is preferred to heat only the portion of the deposition material desired to be evaporated. Heating the material in this way provides uniform, easier to control, flux because these organic materials have poor thermal conduction and can undesirably degrade under certain heating conditions. If the material is heated below its top surface, such as at a side surface or within the bulk of the material, the material can evaporate inconsistently and/or degrade in a more difficult to control manner.

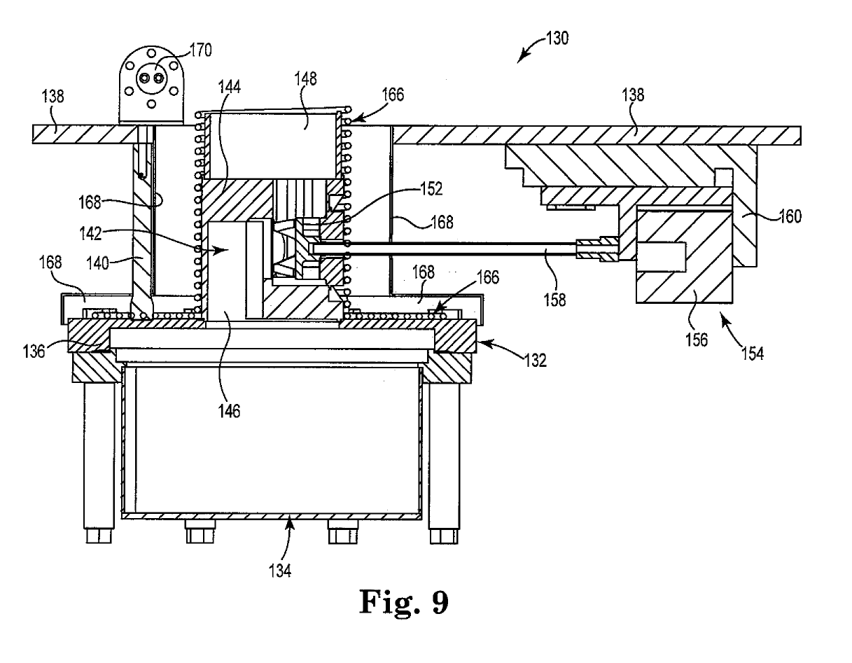

Deposition source 130 shown in FIGS. 9-13 is thus designed to carefully control the thermal profile of the entire deposition source to provide the desired heating characteristics. In particular, closure plate 136 is preferably designed to radiate heat from surface 139 so that at least a portion of the exposed surface of deposition material in crucible 134 is uniformly heated. That is, the exposed surface of deposition material in crucible 134 is heated to provide controllable evaporation of the deposition material with minimal or no degradation of the deposition material. It is noted that surface 139 does not itself need to uniformly radiate thermal energy. For example, in an exemplary embodiment, surface 139 is heated so an outside region of surface 139 is hotter than an inside region of surface 139 where such regions are generally concentric. Parameters that can be considered to design closure plate 136 preferably include at least the design of heating element 166, the design of heat shielding 168, and the design of cooling circuit 221. That is, closure plate 136, heating element 166, heat shielding 168, and cooling circuit 221 along with other aspects of deposition source 130 that affect how surface 139 radiates heat to deposition material provided in crucible 134 are preferably designed to optimize radiation characteristics of surface 139.

As shown, heating element 166 is preferably provided around valve body 144 and across closure plate 136. A single element or plural elements can be used. Plural elements may be controlled together in one or more groups or individually. Heating elements such as those available from Watlow can be used. An exemplary heater provides 100-1000 watts of power. Heat shielding 168 is provided around heater element 166 as shown and preferably comprises one or more layers of appropriate material such as stainless steel, refractory metals or the like. The heat shielding is preferably designed to 1) help redirect radiant heat to the regions desired to be heated, 2) prevent radiant heat from impinging on the valve actuator or other components, and 3) prevent excess radiant heat from impinging on the substrate.

Deposition source 130 shown in FIGS. 7-13 is also preferably designed to minimize and control conductive heat. In particular, the contact area between crucible 134 and closure plate 136 is preferably minimized. Moreover, using a graphite gasket in accordance with the present invention can also function to provide a thermal break or interruption to conductive heat from undesirably heating crucible 134.

Deposition source 130 shown in FIGS. 7-13 also preferably comprises a suitable power connector 170 for providing power to heating element 166. Deposition source 130 also preferably includes one or more temperature sensors such as thermocouple 172 or the like and an appropriate connector 174. A temperature sensor such as a thermocouple is preferably used to provide feedback for control of heating element 166 by a control system (not shown) as conventionally known. In an exemplary configuration, a thermocouple is positioned on the valve body 144. Optional thermocouples can be positioned at the bottom of crucibles 134.

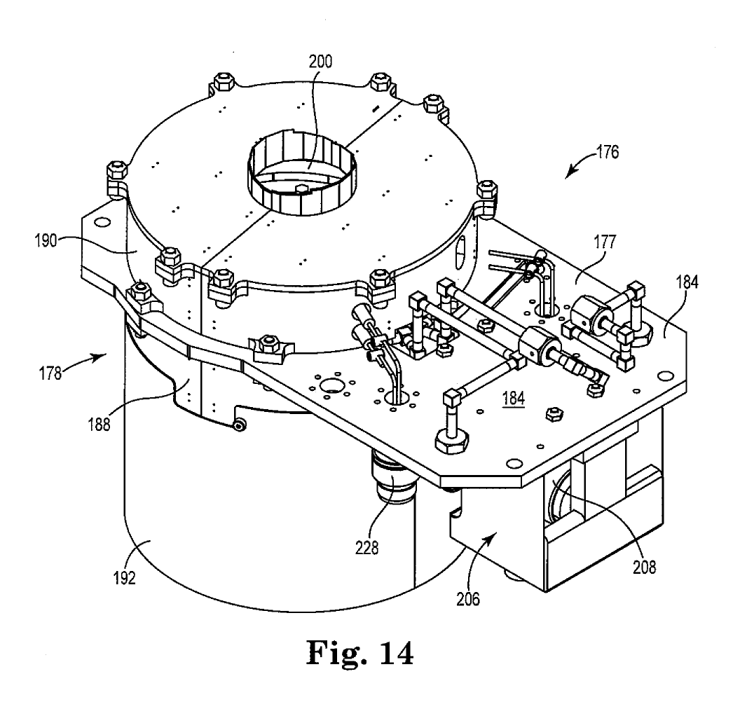

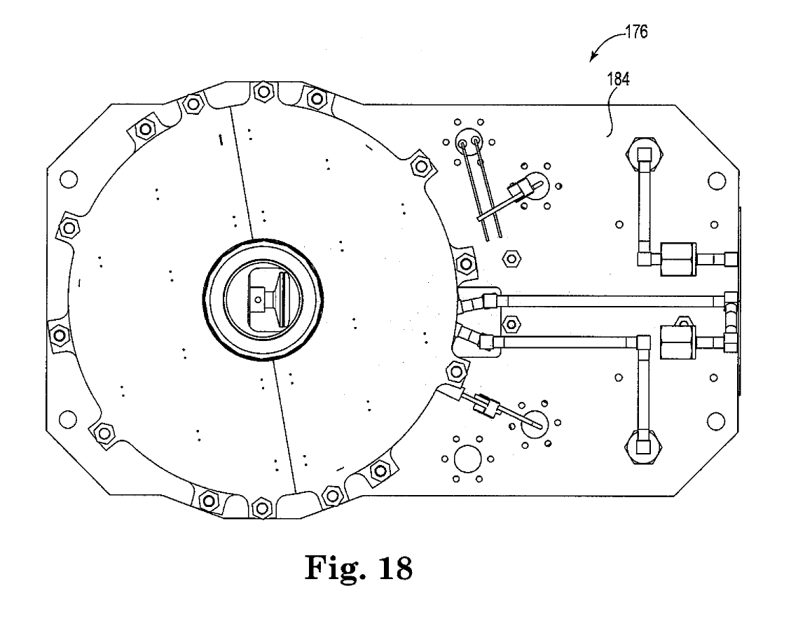

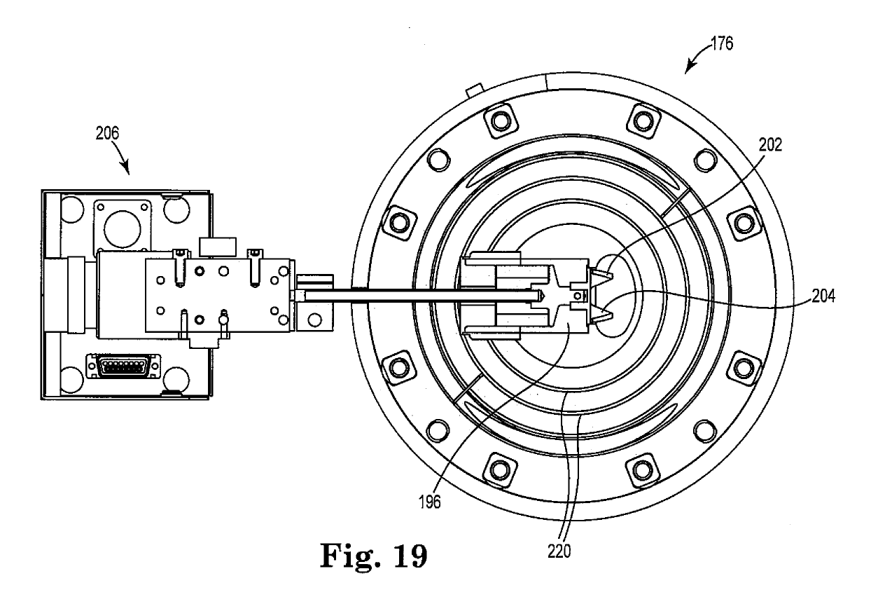

FIGS. 14-21 show another exemplary deposition source 176 in accordance with the present invention. Deposition source 176, as shown, is designed and configured similarly to deposition source 130 described above. Deposition source 176 is preferably designed and configured to be at least partially positioned within a vacuum deposition chamber (not shown) in accordance with the present invention. In a preferred embodiment, deposition source 176 is designed and configured to be substantially or entirely positioned within a vacuum deposition chamber (not shown).

Referring to FIGS. 14-21 generally, deposition source 176 comprises enclosure 178 including crucible 180 and closure plate 182 that are separable from each other. Closure plate 182 is attached to mounting plate 184 by plural support legs 186 mounting plate 184 can be used to mount deposition source 176 within a vacuum deposition chamber (not shown). Crucible 180 is designed to hold desired amount of deposition material and may include any number of chambers or cells including a single interior chamber as illustrated. Exemplary crucibles that can be used are also described in Applicants co-pending U.S. patent application titled “Vapor Deposition Sources and Methods,” having Ser. No. 12/002,526, and attorney docket No. VII0004/US, the entire disclosure of which is incorporated herein for all purposes.

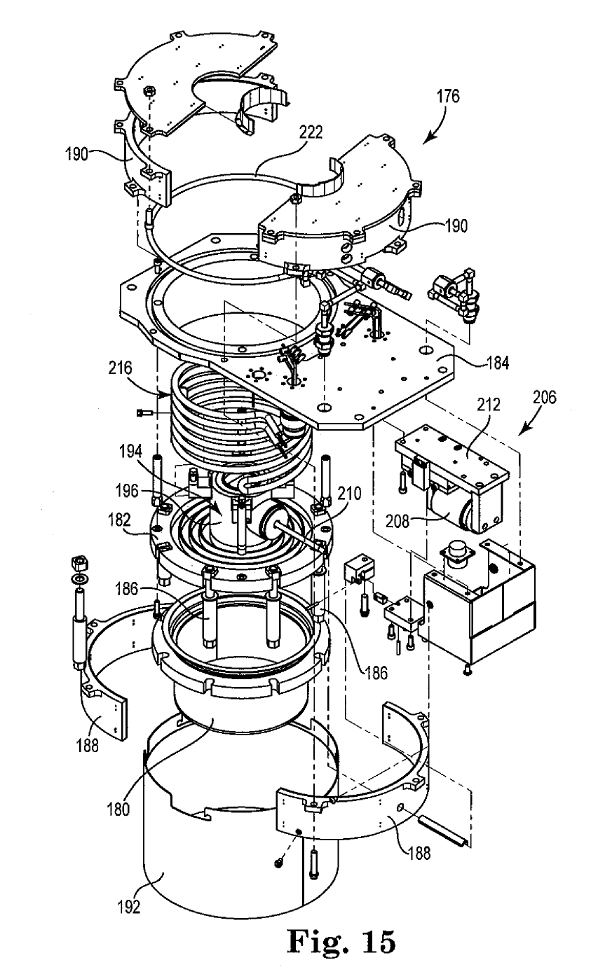

Crucible 180 is designed to be detachable from closure plate 182 such as is illustrated in FIG. 15. An appropriate seal is provided between crucible 180 and closure plate 182. An exemplary preferred seal comprises a graphite gasket that is clamped between a flat surface of crucible 180 and a flat surface of closure plate 182. Seals that include metal gasket and flanges having a knife-edge can also be used.

As illustrated, deposition source 176 comprises first housing 188 positioned below mounting plate 184 and second housing 190 positioned above mounting plate 184. First housing 188 generally surrounds crucible 180 and comprises two semicircular portions as shown. Any number of housing portions can be used. Attached to first housing 188 is heat shield 192. As shown, second housing 190 also comprises two semicircular portions but any number of housing portions can be used.

Closure plate 182 includes valve assembly 194. As described above, valve assembly 194 includes valve body 196 with input and output region, 198 and 200, respectively valve seat 202, valve 204, and valve actuator 206. Valve actuator 206 includes motor 208, driveshaft 210, and mounting plate 212. An exemplary valve that can be used is shown in FIG. 13 and explained above. One preferred drive device that can be used to actuate valve 204 comprises a voice coil. An exemplary voice coil device that can be used is available from H2W Technologies of Valencia Calif. as model No. VCS-10-005-E.

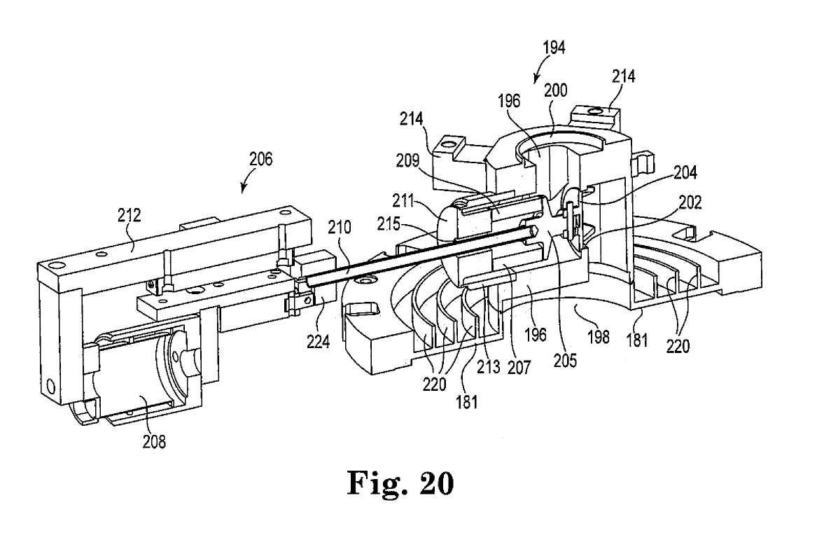

With reference to FIG. 20 in particular, valve 204 is attached to adapter 205. Adapter 205 is attached to driveshaft 210, which is attached to flexible joint 224. Adapter 205 is also connected to flexible bellows 209, which is connected to adapter 211. Adapter 211 is connected to tube 213 that is connected to valve body 196. Driveshaft 210 passes through opening 215 in adapter 211 and is movable to operate valve 204.

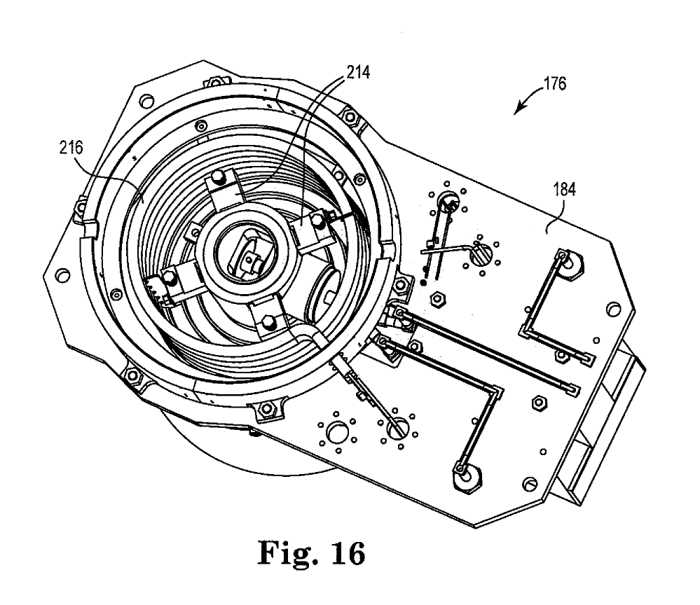

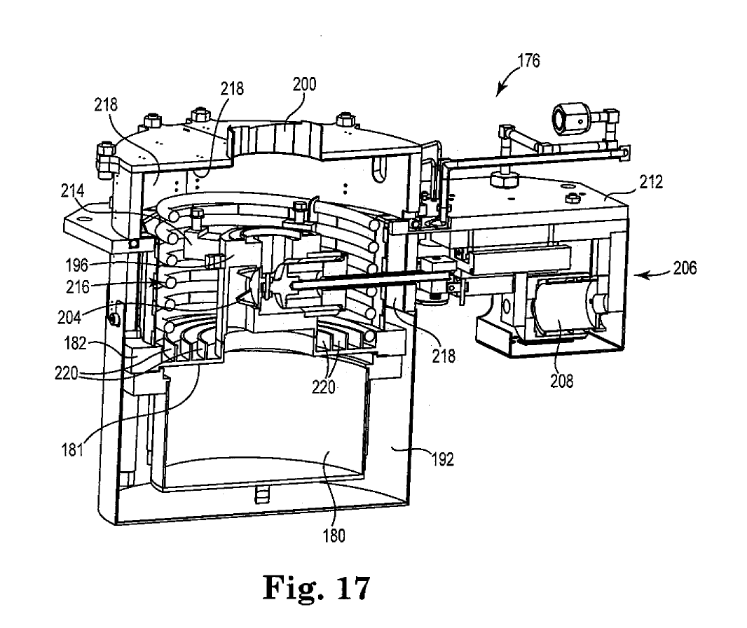

As shown, input side 198 of valve body 196 is attached to closure plate 182 and output side 200 of valve body 196 is configured to be attached to a nozzle (not shown). As can be seen in FIGS. 16 and 17, for example, nozzle mounts 214 can be used to attach a nozzle (not shown) to output side 200 of valve body 196. Exemplary nozzles that can be used are described below. In this configuration, vapor from deposition material provided within crucible 180 enters valve body 196 at input side 198 of valve body 196 and exits valve body 196 at output side 200 of valve body 196 as controlled by valve 204.

As explained above, deposition source 176 is preferably designed to heat deposition material provided within crucible 180 in a controlled manner. In particular, deposition source 176 is preferably designed so surface 181 of closure plate 182 radiates heat to deposition material provided within crucible 180 in a manner that causes uniform heating of such deposition material. In particular, when deposition material comprises organic material such as is used in the manufacture of organic light emitting devices, the material is preferably heated from above. That is, it is preferred to provide radiant heat to the top surface of the deposition material provided in crucible 180. Heating the material in this way provides uniform, easier to control, flux because these organic materials have poor thermal conduction. If the material is heated below its top surface, such as at a side surface or within the bulk of the material, the material can evaporate inconsistently and in a more difficult to control manner.

Exemplary deposition source 176 shown in FIGS. 13-21 is thus designed to carefully control the thermal profile of the entire deposition source to provide the desired heating characteristics. As shown, heating element 216 is provided around the valve body 196. A single element or plural elements may be used. Plural elements may be controlled together in one or more groups or individually. Heating elements such as those available from Watlow can be used. Heat shielding 218 is provided around heating element 216 as shown in preferably comprises one or more layers of appropriate material such as refractory metals or the like. Heat shielding is 218 is preferably designed to 1) help redirect radiant heat to the regions desired to be heated, 2) prevent radiant heat from impinging on valve actuator 206 or other components, and 3) prevent excess radiant heat from impinging on a substrate.

As can be seen in FIG. 17, for example, closure plate 182 includes plural optional concentric heat distribution fins 220. Fins 220 are designed to help spread heat thus making the temperature of closure plate 182 more uniform and/or controllable. Surface 181 of closure plate 182 faces the deposition material in crucible 180 and radiates heat to the top surface of the deposition material. Optional heating fins 220 provide more controllable heating of the top surface of the deposition material in accordance with the present invention. Heating fins 220, if used, may be arcuate, linear, or combinations thereof, for example. Any structure having geometry, material, and/or shape capable of evening out the heating of closure plate 182 may be used.

Deposition source 176 shown in FIGS. 14-21 is also preferably designed to minimize and control conductive heat. The contact area between crucible 180 and closure plate 182 is preferably minimized. Moreover, using a graphite gasket in accordance with the present invention can also function to provide a thermal break or interruption to conductive heat from undesirably heating crucible 180.

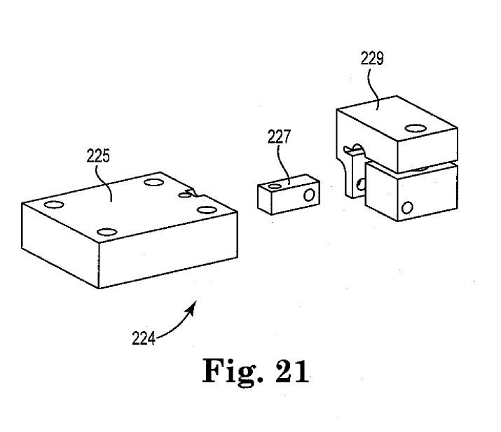

Deposition source 176 is also preferably designed to minimize heat from reaching valve actuator 206. For example, as can be seen in FIG. 15, cooling circuit 221 preferably includes tube 222 which is preferably positioned in contact with mounting plate 184 to help minimize heating of mounting plate 184, which could cause heating of valve actuator 206. Appropriate heat shielding is also preferably used Cooling circuit 221 may comprise any cooling system that functions to provide the desired cooling such as systems including liquid, and/or gas cooling fluid. Also, flexible joint 224 is preferably used to connect rod 226 connected to valve 204 and valve actuator 206. An exemplary flexible joint 224 that can be used is shown in FIG. 21 and includes body 225, pin 227, and clamp 229. Flexible joint 224 also provides a thermal break that helps minimize heating of valve actuator 206 by conductive heat.

Deposition source 126 shown in FIGS. 14-21 also preferably comprises a suitable power connector 228 for providing power to heating element 216. Vacuum source 176 also preferably includes one or more temperature sensors such as a thermocouple or the like and an appropriate connector(s). A temperature sensor such as a thermocouple is preferably used to provide feedback for control of heating element 216 by a control system (not shown) as conventionally known. In an exemplary configuration, a thermocouple is positioned adjacent to valve body 196. Optional thermocouples can be positioned as desired such as in contact with crucible 180, for example.

Any suitable materials can be used for the deposition sources described herein. As an example, an embodiment of a deposition source in accordance with the present invention may use aluminum for mounting plates and structure, and titanium for the valve body, valve closure plate, and crucible. Stainless steel can be used for heat shielding.

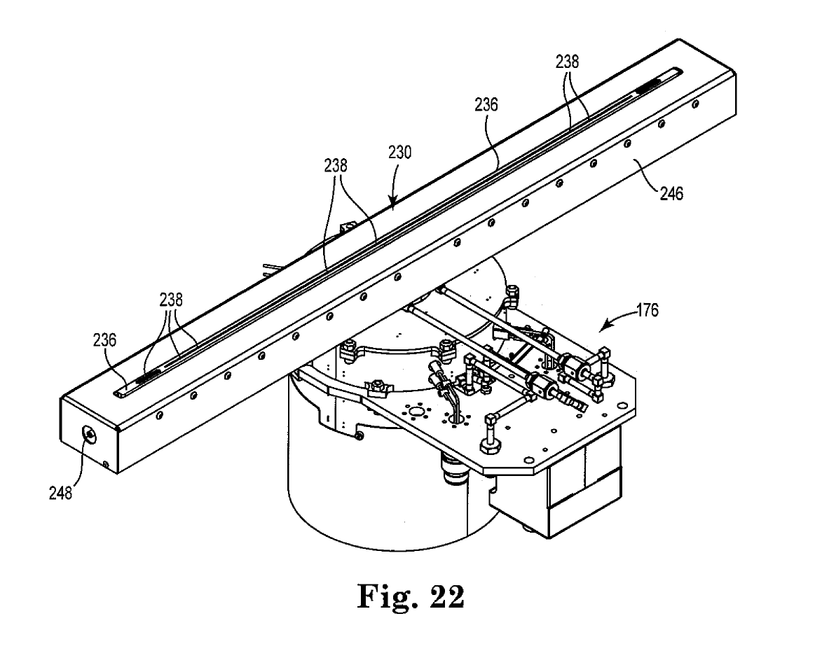

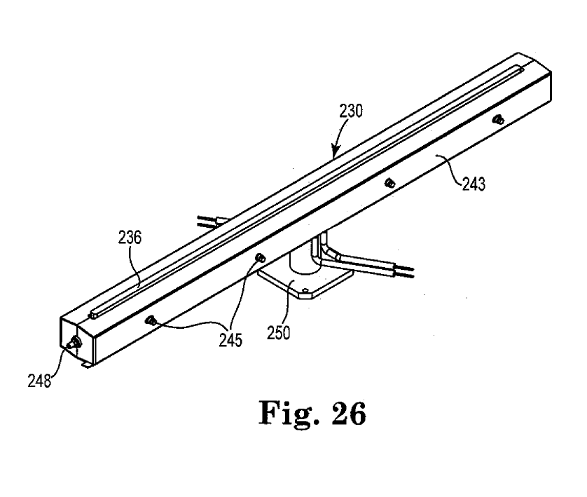

In FIGS. 22-28 exemplary nozzle assembly 230 in accordance with the present invention is illustrated. In FIGS. 22-25, nozzle assembly 230 is illustrated as operatively attached to deposition source 176 shown in FIGS. 14-21 and as described above. In FIGS. 26-28 nozzle assembly 230 is shown separately from deposition source 176.

Referring to FIGS. 22-28 generally, nozzle assembly 230, as shown, includes tube 232 with conductance region 234, nozzle plate 236 with orifices 238, heating elements 240, heat shielding 242, cooling coil 244, cooling enclosure 246, flux monitoring jet 248, and mounting flange 250.

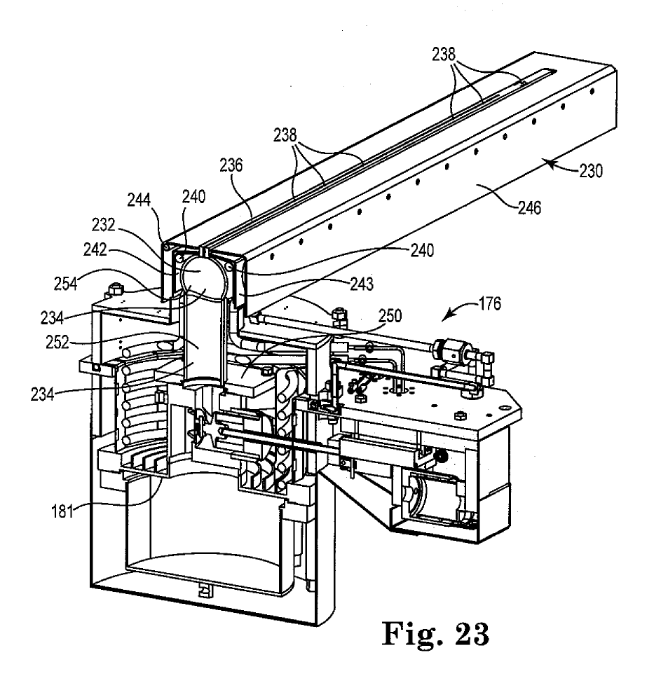

Referring to FIG. 23 in particular, a cross-sectional view of nozzle assembly 230 and deposition source 176 is shown. Nozzle assembly 230 is operatively connected to deposition source 176 by mounting flange 177. Preferably a gasket comprising flexible graphite is used. Any desired mounting and/or connection technique can be used including threaded connections, fasteners, clamps, and the like.

Mounting flange 177 is connected to first tube 252, which provides conductance of vaporized deposition material to second tube 254. As shown, first tube 252 is connected to second tube 254 so second tube 254 is generally at about ninety degrees to first tube 252. Second tube 254 includes nozzle plate 236, which includes plural orifices 238 for directing vaporized deposition material to a substrate positioned within a vacuum chamber (not shown). Any arrangement of orifices 238 can be used including the use of a single orifice. The geometry of the deposition chamber, deposition material, and substrate, for example, are preferably considered in determining the arrangement of orifices 238 and respective positioning of orifices 238.

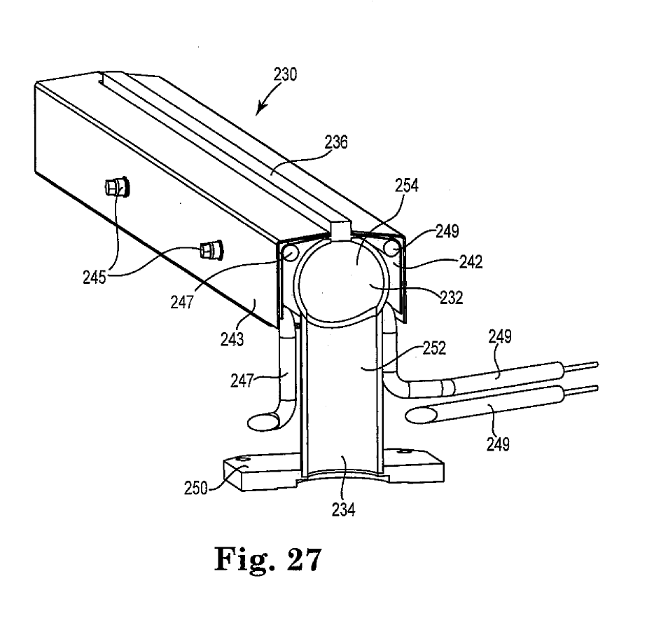

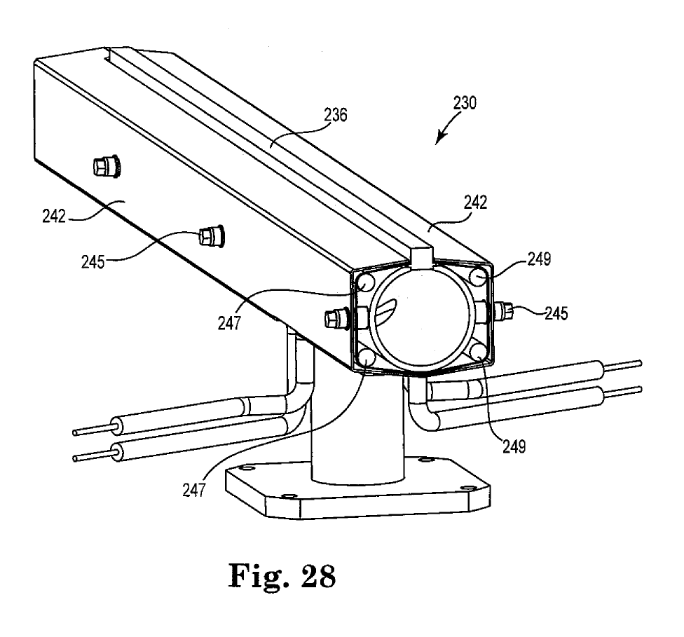

Referring now to FIGS. 27 and 28, nozzle assembly 230 is shown with cooling enclosure 246 and cooling coil 244 removed. As shown, first and second heating elements, 247 and 249, respectively, heat shielding 242, and heat shielding enclosure 243 are positioned around second tube 254. Exemplary heat shielding 242 preferably comprises plural layers of knurled stainless, steel material. First and second heating elements, 247 and 249, respectively preferably comprise heating elements capable of sufficiently heating second tube 254 to minimize condensation of deposition material on second tube 254. For organic materials used with typical organic light admitting devices first and second heating elements, 247 and 249, respectively, are preferably capable of heating second tube 254 to about 500-700 degrees Celsius. Heaters from Watlow, for example, can be used. An exemplary heater provides 200-2000 watts of power.

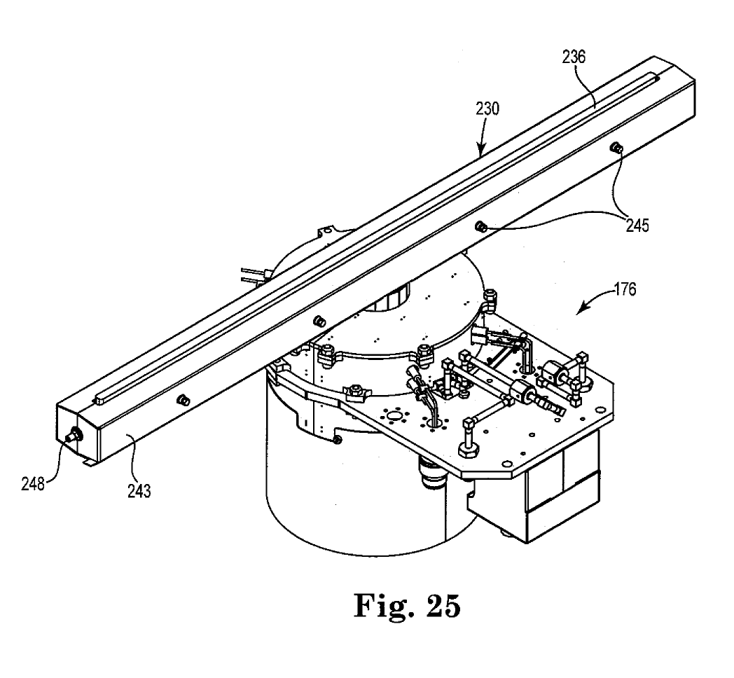

Referring now to FIG. 23, cooling enclosure 246 that includes cooling coil 244 positioned around heat shielding 242 and heat shielding enclosure 243 is shown. Cooling enclosure 246 is attached to heat shielding enclosure 243 at standoffs 245 positioned along sidewalls of heat shielding enclosure 243 as can be seen in FIG. 25, for example. Cooling coil 244 is designed to help remove excess heat from nozzle assembly 230 to minimize radiation of heat from nozzle assembly 230 to a substrate. Preferably cooling coil 244 is designed for use with water. Cooling coil 244 is preferably functionally integrated with the water cooling circuit of the deposition source.

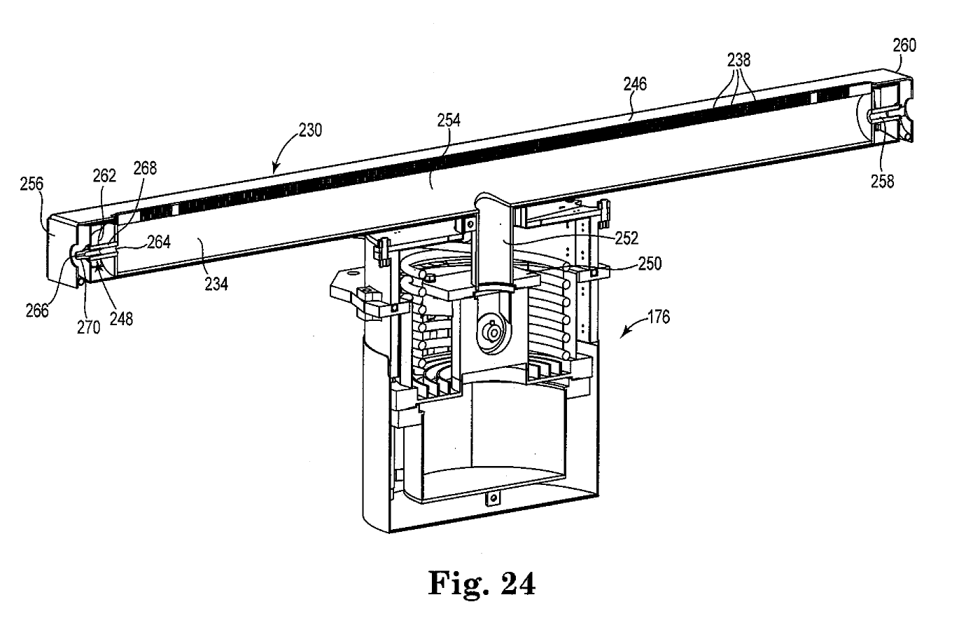

Exemplary nozzle assembly 230 also preferably comprises one or more flux monitoring jet(s) as shown best in FIGS. 24 and 25. As shown, nozzle assembly 230 comprises first flux monitoring jet 248 at first end 256 of nozzle assembly 230 and second optional flux monitoring jet 258 at second end 260 of nozzle assembly 230. Second flux monitoring jet 258 is plugged, as shown, but can be used if desired. Flux monitoring jet 248 preferably comprises cylindrical tube 262 with first end 264 in fluid communication with conductance region 234 of second tube 254 and second end 266 capable of providing vaporized deposition material to a location for measurement by an instrument capable of measuring vapor flux and/or pressure. For example, a beam flux monitor (not shown) such as a quartz crystal sensor can be used. Cylindrical tube 262 preferably comprises first portion 268 with a first inside diameter and second adjacent portion 270 with a second inside diameter less than the first inside diameter of first portion 268. The reduction in diameter is designed to reduce the flux by a known factor as compared to the flux of the nozzle orifices 238. In this way, flux at monitoring jet 248 can be measured and correlated to the flux of the nozzle orifices 238. Advantageously, this allows flux to be measured remotely and reduces the flux being measured by the measurement instrument. Reducing the flux in this way extends the life of the flux monitoring instrument, particularly when a quartz crystal sensor is used. Additionally, the flux monitoring instrument can be located outside of the deposition zone.

Any suitable materials can be used for the nozzles described herein. As an example, an embodiment of a nozzle in accordance with the present invention may include a titanium inner tube, stainless steel heat shielding, stainless steel water lines, and an aluminum enclosure.

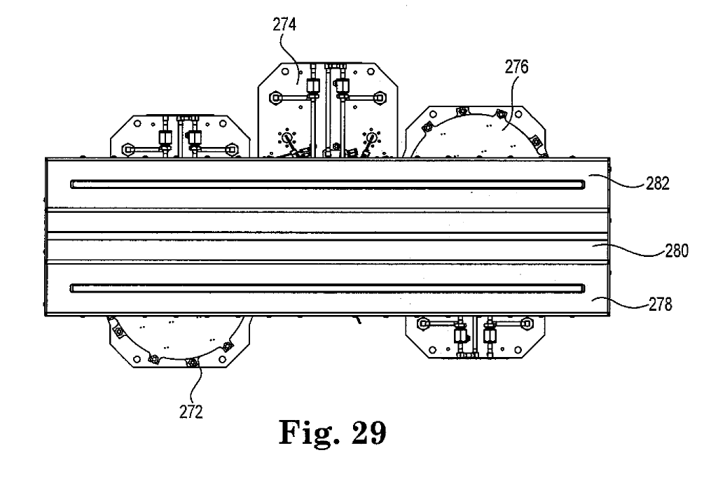

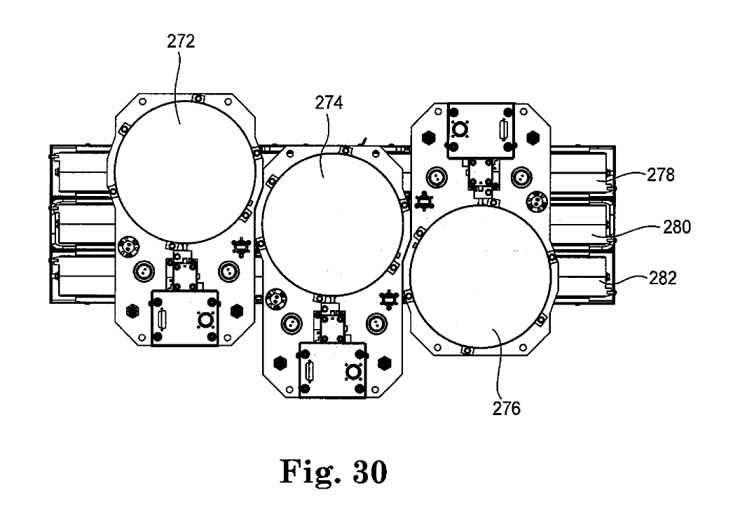

FIGS. 29 and 30 schematically illustrate an exemplary configuration for deposition sources and nozzles in accordance with the present invention. As shown three deposition sources 272, 274, and 276, respectively, include nozzles 278, 280, and 282, respectively, configured to provide a bank of deposition sources and nozzles. In this way, different deposition material can be provided in each deposition source if desired. Any number of deposition sources can be used.

The present invention has now been described with reference to several exemplary embodiments thereof. The entire disclosure of any patent or patent application identified herein is hereby incorporated by reference for all purposes. The foregoing disclosure has been provided for clarity of understanding by those skilled in the art of vacuum deposition. No unnecessary limitations should be taken from the foregoing disclosure. It will be apparent to those skilled in the art that changes can be made in the exemplary embodiments described herein without departing from the scope of the present invention. Thus, the scope of the present invention should not be limited to the exemplary structures and methods described herein, but only by the structures and methods described by the language of the claims and the equivalents of those claimed structures and methods.

What is claimed is:

1. A vacuum deposition source, the vacuum deposition source comprising:
an enclosure configured to be positioned within a vacuum chamber of a vacuum deposition system, the enclosure comprising one or more portions separable from each other;
a valve positioned at least partially within the enclosure, the valve having an input side and an output side;
a crucible comprising a closure plate wherein the closure plate is in communication with the input side of the valve;
a nozzle comprising at least one exit orifice, the nozzle at least partially positioned in the enclosure and in communication with the output side of the valve;
a heating device at least partially surrounding the valve; and
a valve actuator operatively connected to the valve and configured to operate in vacuum.

2. The deposition source of claim 1, comprising a graphite sealing gasket positioned between the crucible and the closure plate.

3. The deposition source of claim 2, wherein the graphite sealing gasket comprises Grafoil® single layer material.

4. The deposition source of claim 1, wherein the closure plate comprises one or more fins configured to control heat transfer between the heating device and the crucible.

5. The deposition source of claim 4, wherein the fins comprise one or more concentric rings.

6. The deposition source of claim 1, wherein the heating device comprises a tubular heater coil.

7. The deposition source of claim 1, wherein the valve actuator comprises a voice coil.

8. The deposition source of claim 1, comprising a housing at least partially surrounding the enclosure.

9. The deposition source of claim 1, comprising at least one liquid cooling circuit.

10. The deposition source of claim 1, wherein the nozzle comprises a plurality of output orifices and a flux monitoring jet distinct from the plurality of output orifices wherein the flux monitoring jet emits a flux proportional to the output flux of the plurality of output orifices.

11. The deposition source of claim 1, wherein the nozzle comprises a first enclosure having an internal space, a conductance tube provided within at least a portion of the internal space of the first enclosure, and a heating element provided within at least a portion of the internal space of the first enclosure.

12. The deposition source of claim 11, wherein the nozzle comprises a second enclosure having an internal space wherein the first enclosure is provided within at least a portion of the internal space of the second enclosure.

13. The deposition source of claim 12, comprising a liquid cooling circuit provided in at least a portion of the internal space of the second enclosure.

14. The deposition source of claim 1 in combination with a vacuum deposition system.

15. The combination of claim 14, wherein the vacuum deposition system comprises a system for manufacturing at least a portion of an organic light-emitting device

16. A vacuum deposition system, the vacuum deposition system comprising:
a vacuum chamber;
an enclosure configured to be positioned within a vacuum chamber of a vacuum deposition system, the enclosure comprising one or more portions separable from each other; a valve positioned at least partially within the enclosure, the valve having an input side and an output side; a crucible comprising a closure plate wherein the closure plate is in communication with the input side of the valve; a nozzle comprising at least one exit orifice, the nozzle at least partially positioned in the enclosure and in communication with the output side of the valve; a heating device at least partially surrounding the valve; and a valve actuator operatively connected to the valve and configured to operate in vacuum;
a deposition material provided in the crucible; and
a substrate positioned in the vacuum chamber and relative to the nozzle of the vacuum deposition source.

17. The vacuum deposition system of claim 16, wherein the deposition material comprises one or more of a granular, flake, powder, and liquid consistency.

18. The vacuum deposition system of claim 16, wherein the deposition material comprises one or more inorganic components.

19. The vacuum deposition system of claim 18, wherein the deposition material comprises Aluminum Tris (8-Hydroxyquinoline).

20. The vacuum deposition system of claim 16, wherein the substrate comprises at least a portion of an organic light-emitting device.

21. The vacuum deposition system of claim 16, wherein the vacuum deposition source is configured to move relative to the substrate.

22. A vacuum deposition source, the vacuum deposition source comprising:
an enclosure configured to be positioned within a vacuum chamber of a vacuum deposition system, the enclosure comprising one or more portions separable from each other;
a valve positioned at least partially within the enclosure, the valve having an input side and an output side;
a crucible comprising a closure plate wherein the closure plate is in communication with the input side of the valve;
a nozzle at least partially positioned in the enclosure and in communication with the output side of the valve, the nozzle comprising a plurality of output orifices and a flux monitoring jet distinct from the plurality of output orifices wherein the flux monitoring jet emits a flux proportional to the output flux of the plurality of output orifices;
a heating device at least partially surrounding the valve; and
a valve actuator operatively connected to the valve and configured to operate in vacuum.

23. The deposition source of claim 22, wherein the nozzle comprises a first enclosure having an internal space, a conductance tube provided within at least a portion of the internal space of the first enclosure, and a heating element provided within at least a portion of the internal space of the first enclosure.

24. The deposition source of claim 23, wherein the nozzle comprises a second enclosure having an internal space wherein the first enclosure is provided within at least a portion of the internal space of the second enclosure.

25. The deposition source of claim 24, comprising a liquid cooling circuit provided in at least a portion of the internal space of the second enclosure.
